(19) United States
(12) Patent Application Publication
(10) Pub. No.: US 2024/0120883 A1
(43) Pub. Date: Apr. 11, 2024

(54) VOLTAGE-CONTROLLED OSCILLATOR AND BIAS GENERATION CIRCUIT

(71) Applicant: Nippon Telegraph and Telephone Corporation, Tokyo (JP)

(72) Inventors: Teruo Jo, Tokyo (JP); Munehiko Nagatani, Tokyo (JP); Hideyuki Nosaka, Tokyo (JP)

(21) Appl. No.: 18/546,172

(22) PCT Filed: Feb. 18, 2021
(86) PCT No.: PCT/JP2021/006159

§ 371 Date: Aug. 11, 2023

(51) Int. Cl. H03B 5/24

(52) U.S. Cl. CPC H03B 5/24

(57) ABSTRACT

A voltage-controlled oscillator includes a first unit cell, a second unit cell that is connected in parallel to the first unit cell via transmission lines, a compensation unit cell that is connected in parallel with the first unit cell and the second unit cell between the first unit cell and the second unit cell, and an input termination resistor that is connected to a power supply voltage terminal of each of the first unit cell, the second unit cell, and the compensation unit cell. Symmetrical voltages are supplied to the first unit cell and the second unit cell, and the compensation unit cell compensates for a gain by the first unit cell or the second unit cell.

### CROSS-REFERENCE TO RELATED APPLICATIONS

This application is a national phase entry of PCT Application No. PCT/JP2021/006159, filed on Feb. 18, 2021, which application is hereby incorporated herein by reference.

### TECHNICAL FIELD

The present invention relates to a voltage-controlled oscillator and a bias generation circuit that operate in a wide band.

### BACKGROUND

A voltage-controlled oscillator (hereinafter, referred to as a “VCO”) having a wide variable frequency range is required for various applications such as optical communication, wireless communication, and radar. As an architecture of a VCO capable of realizing a high center frequency and a wide variable range, a distributed VCO in a reverse gain mode illustrated in FIG. 7 has been proposed (Non Patent Literature 1).

A basic configuration is based on a distributed amplifier circuit (hereinafter, referred to as a “distributed amplifier”), and includes, for example, a plurality of unit cells 51 and 52, transmission lines 53_1 to 53_7, and an input termination resistor 54. In the related art, by symmetrically changing bias voltages to be applied to a pair of (two) adjacent unit cells 51 and 52 using the unit cells, a time constant of a loop through which a signal passes can be changed. Thus, it is possible to change an oscillation frequency.

Here, “symmetrically changing bias voltages” means that a bias voltage to be supplied to one unit cell is increased and a bias voltage to be supplied to the other unit cell is decreased by the increased voltage. In other words, the bias voltages to be supplied to both unit cells are changed such that a sum of the bias voltage to be supplied to one unit cell and the bias voltage to be supplied to the other unit cell is constant.

The oscillation frequency is determined as follows. As illustrated in FIG. 7, a high voltage Vb1 is applied to a bias terminal 55_1 such that the unit cell (1) 51 is in a complete ON state (a state where a gain characteristic is highest), and a low voltage Vb2 is applied to a bias terminal 55_2 such that the unit cell (2) 52 is in a complete OFF state (a state where a gain characteristic is lowest). At this time, as indicated by a dotted arrow in FIG. 7, a short loop is formed, and the oscillation frequency of the VCO becomes a maximum oscillation frequency fmax (5_1 in FIG. 7).

On the other hand, a low voltage Vb1 is applied to the bias terminal 55_1 such that the unit cell (1) 51 is in a complete OFF state, and a high voltage Vb2 is applied to the bias terminal 55_2 such that the unit cell (2) 52 is in a complete ON state. At this time, as indicated by a dotted arrow in FIG. 7, a long loop is formed, and an output of the VCO becomes a minimum oscillation frequency fmin (5_2 in FIG. 7).

In this configuration, by symmetrically applying voltages to the bias terminal 55_1 and the bias terminal 55_2 such that the states of the unit cell (1) 51 and the unit cell (2) 52 are in an intermediate state between ON and OFF, it is possible to continuously change the oscillation frequency of the VCO between fmin and fmax.

### CITATION LIST

### Non Patent Literature

Non Patent Literature 1: Acampora, A., A. Collado, and A. Georgiadis. “Nonlinear analysis and optimization of a distributed voltage controlled oscillator for cognitive radio” 2010 IEEE International Microwave Workshop Series on RF Front-ends for Software Defined and Cognitive Radio Solutions (IMWS). IEEE, 2010.

### SUMMARY

### Technical Problem

However, in the configuration in the related art, in a case where the voltages of the bias terminal 55_1 and the bias terminal 55_2 are both at an intermediate potential, the oscillation may be stopped.

FIG. 8 illustrates simulation results of the oscillation frequency and the output power when the voltages of the bias terminal 55_1 and the bias terminal 55_2 are changed in the configuration in the related art. The oscillation is stopped in a region where the voltage Vb1 of the bias terminal 55_1 is −2.9 V to −2.8 V and the voltage Vb2 of the bias terminal 55_2 is −2.8 V to −2.9 V.

The reason why the oscillation is stopped can be described using a characteristic of an open loop as follows. Generally, as a condition for oscillation to continue, a gain needs to be 0 dB or higher at a frequency at which a phase rotation of an open loop is 360 degrees.

FIG. 9 illustrates characteristics of an open loop in a case where oscillation is continued (in a case where the voltages Vb1 and Vb2 of the bias terminal 55_1 and the bias terminal 55_2 are respectively −3.4 V and −2.3 V, solid lines in FIG. 9) and in a case where oscillation is stopped (in a case where the voltages Vb1 and Vb2 of the bias terminal 55_1 and the bias terminal 55_2 are respectively −2.9 V and −2.8 V, broken lines in FIG. 9). In the characteristics of the open loop, a gain and a phase are changed by applying the bias. Thus, the open loop enters an oscillation state. Here, the oscillation frequency changes due to a change in the bias.

In a case where oscillation is continued (Vb1=−3.4 V, Vb2=−2.3 V), the phase rotates as the frequency increases, and becomes 360 degrees at a frequency of approximately 70 GHz. In addition, the gain decreases as the frequency increases, and is approximately 4 dB when the frequency is approximately 70 GHz. As described above, the gain at the frequency at which the phase is 360 degrees is 0 (zero) dB or higher.

On the other hand, in a case where oscillation is stopped (Vb1=−2.9 V, Vb2=−2.8 V), the phase rotates as the frequency increases, and becomes 360 degrees at a frequency of approximately 100 GHz. In addition, the gain decreases as the frequency increases, becomes 0 (zero) dB at a frequency of approximately 55 GHz, and becomes 0 (zero) dB or lower when the frequency is approximately 100 GHz.

As described above, the gain at the frequency at which the phase is 360 degrees is 0 dB or higher in a case where oscillation is continued, and is 0 dB or lower in a case where oscillation is stopped.

For this reason, an oscillator that operates under a condition in which oscillation is stopped by a bias voltage cannot continuously change the frequency from fmin to fmax. As a result, there is a problem that a variable range (frequency band) becomes narrow.

### Solution to Problem

In order to solve the above problems, there is provided a voltage-controlled oscillator including: a first unit cell; a second unit cell that is connected in parallel to the first unit cell via transmission lines; a compensation unit cell that is connected in parallel with the first unit cell and the second unit cell between the first unit cell and the second unit cell; and an input termination resistor that is connected to a power supply voltage terminal of each of the first unit cell, the second unit cell, and the compensation unit cell, in which symmetrical voltages are supplied to the first unit cell and the second unit cell and the compensation unit cell compensates for a gain by the first unit cell or the second unit cell.

### Advantageous Effects of Embodiments of the Invention

According to embodiments of the present invention, it is possible to provide a voltage-controlled oscillator and a bias generation circuit having a wide oscillation frequency band.

### BRIEF DESCRIPTION OF THE DRAWINGS

FIG. 1A is a circuit diagram illustrating a configuration of a voltage-controlled oscillator according to a first embodiment of the present invention.

FIG. 1B is a circuit diagram illustrating a configuration of a unit cell in the voltage-controlled oscillator according to the first embodiment of the present invention.

FIG. 2 is a diagram for explaining an operation of the voltage-controlled oscillator according to the first embodiment of the present invention.

FIG. 3 is a diagram for explaining an operation of the voltage-controlled oscillator according to the first embodiment of the present invention.

FIG. 4 is a circuit diagram illustrating a configuration of a voltage-controlled oscillator according to a modification example of the first embodiment of the present invention.

FIG. 5 is a circuit diagram illustrating a configuration of a voltage-controlled oscillator according to a modification example of the first embodiment of the present invention.

FIG. 6 is a circuit diagram illustrating a configuration of a bias generation circuit in a voltage-controlled oscillator according to a second embodiment of the present invention.

FIG. 7 is a diagram for explaining an operation of a voltage-controlled oscillator in the related art.

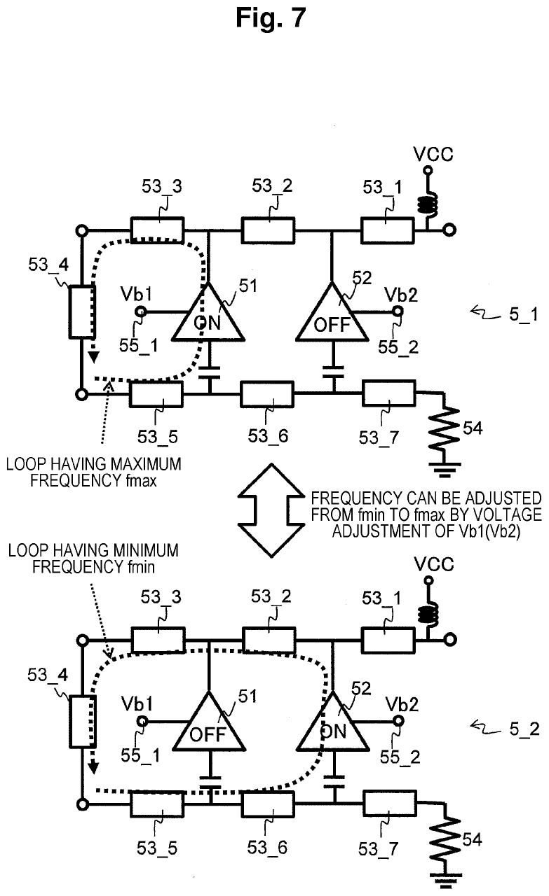

FIG. 8 is a diagram for explaining an operation of the voltage-controlled oscillator in the related art.

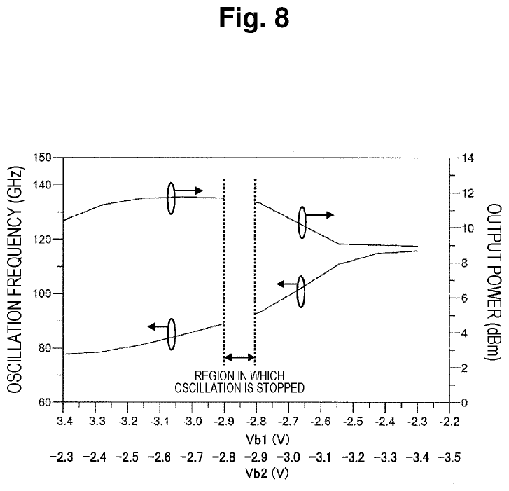

FIG. 9 is a diagram for explaining an operation of the voltage-controlled oscillator in the related art.

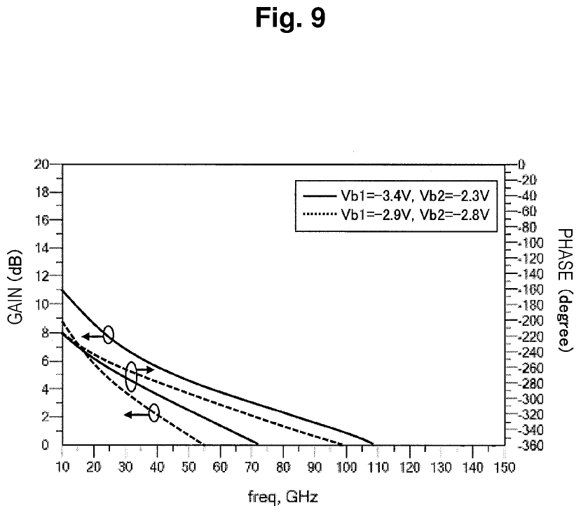

### DETAILED DESCRIPTION OF ILLUSTRATIVE EMBODIMENTS

### First Embodiment

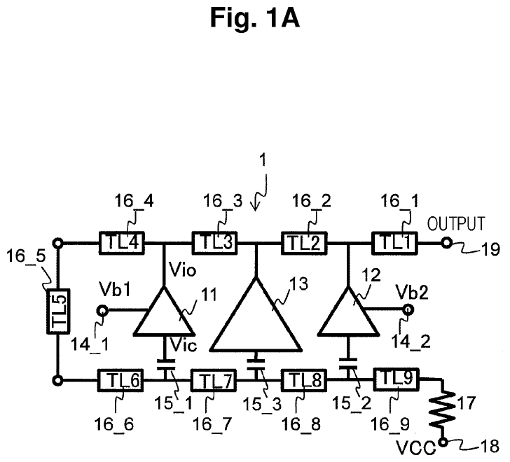

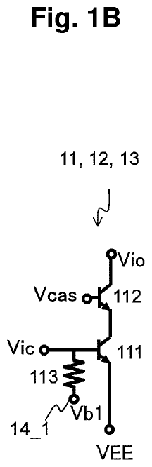

A voltage-controlled oscillator according to a first embodiment of the present invention will be described with reference to FIG. 1A to FIG. 3.

### Configuration of Voltage-Controlled Oscillator

A voltage-controlled oscillator 1 according to the present embodiment is a distributed voltage-controlled oscillator (VCO), and as illustrated in FIG. 1A, includes a first unit cell 11 including a bias terminal 14_1, a second unit cell 12 including a bias terminal 14_2, a compensation unit cell 13, transmission lines (TL1 to TL9) 16_1 to 16_9, and an input termination resistor 17.

Here, the first unit cell 11 and the second unit cell 12 are connected in parallel via the transmission lines, and the compensation unit cell 13 is connected in parallel between the first unit cell 11 and the second unit cell 12. AC coupling capacitors 15_1 to 15_3 are respectively connected to the first unit cell 11, the second unit cell 12, and the compensation unit cell 13.

In addition, a voltage Vb1 is applied to the bias terminal 14_1, and a voltage Vb2 is applied to the bias terminal 14_2. In addition, a voltage is supplied to the compensation unit cell 13 such that the compensation unit cell 13 enters a constant operation state (ON) (fixed bias state).

In addition, the input termination resistor 17 is connected to a power supply voltage VCC terminal 18 of each unit cell, and a power supply voltage VCC of each unit cell is supplied from one end of the input termination resistor 17.

Further, an oscillation signal is output from an output terminal 19.

As a circuit configuration of each of the first unit cell 11, the second unit cell 12, and the compensation unit cell 13, for example, a cascode connection circuit is used as illustrated in FIG. 1B. In the cascode connection circuit, two transistors 11 and 112 are connected in series. In one transistor 11, a voltage VEE is supplied to an emitter, and a base is connected to a Vic terminal and is connected to a Vb1 bias terminal 14_1 via a resistor 113. In the other transistor 112, a voltage Vcas is input to a base, and a Vio terminal is connected to a collector. The cascode connection circuit can reduce a mirror effect and improve a gain characteristic of an open loop.

The circuit configuration of each of the first unit cell 11, the second unit cell 12, and the compensation unit cell 13 is not limited thereto. An amplifier circuit using one transistor may be used.

In addition, characteristic impedance of each of the transmission lines (TL1 to TL9) 16_1 to 16_9 matches impedance of the input termination resistor 17, including input/output parasitic capacitance of each unit cell.

In addition, the voltage VCC of each unit cell is supplied from one end of the input termination resistor 17.

In the voltage-controlled oscillator 1, the biases to be supplied to the first unit cell 11 and the second unit cell 12 are symmetrically changed. That is, the bias voltage to be supplied to one unit cell (for example, the first unit cell 11) is increased, and the bias voltage to be supplied to the other unit cell (for example, the second unit cell 12) is decreased by the increased voltage. At this time, a sum of the bias voltages to be supplied to the first unit cell 11 and the second unit cell 12 is constant.

In addition, the compensation unit cell 13 includes a transistor to which a bias voltage (fixed bias) is applied such that the compensation unit cell 13 enters a constant ON state. A gain characteristic is improved by the compensation unit cell 13. Thus, even in the case of intermediate potential at which gains of the unit cells decrease together, the oscillation can be continued.

According to the voltage-controlled oscillator of the present embodiment, the frequency can be continuously changed from fmin to fmax, and the variable range (frequency band) can be widened.

### Operation of Voltage-Controlled Oscillator

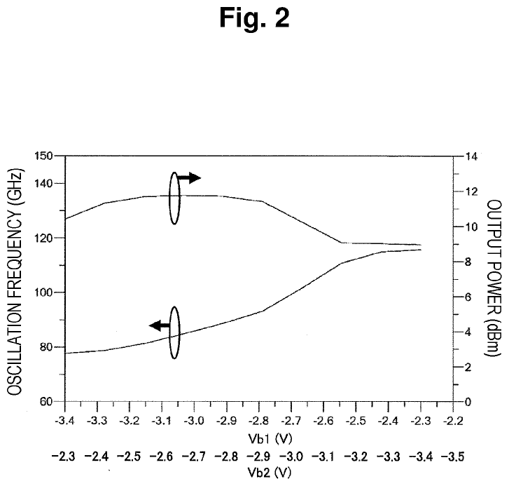

FIG. 2 illustrates dependencies of an oscillation frequency and an output power on the voltages Vb1 and Vb2 in the voltage-controlled oscillator 1. The dependencies on the voltages Vb1 and Vb2 are obtained by simulation. The oscillation is continued even under a bias condition where oscillation is stopped in the configuration in the related art, and the oscillation frequency continuously changes between fmin and fmax.

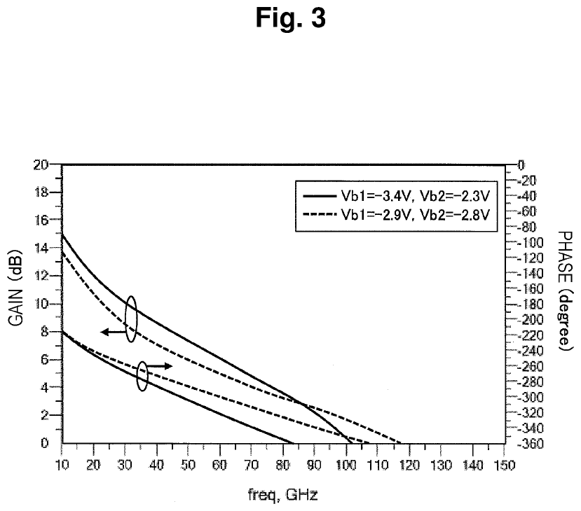

FIG. 3 illustrates a characteristic of an open loop of the voltage-controlled oscillator (distributed VCO) 1. In the configuration in the related art, under a bias condition (Vb1=−2.9 V, Vb2=−2.8 V, a dashed line in FIG. 3) where oscillation is stopped, a gain at a frequency at which the phase rotation is 360 degrees is 0 dB or lower.

On the other hand, in the voltage-controlled oscillator 1, under the same bias condition, when the phase rotation is 360 degrees, the gain is approximately 1 dB and is 0 dB or higher.

As described above, in the voltage-controlled oscillator 1, a gain due to the first unit cell 11 or the second unit cell 12 can be compensated by the compensation unit cell 13, and thus the gain can be set to 0 dB or higher. Therefore, oscillation can be maintained. By using this configuration, a variable range (range in which the frequency can be changed) can be extended from 7 GHz in the related art to 38 GHz.

According to the voltage-controlled oscillator of the present embodiment, the frequency can be continuously changed from fmin to fmax, and the variable range can be widened.

In addition, by applying the VCC from the input termination resistor, an inductor for supplying the VCC that is required in the related art can be omitted.

Further, by matching the characteristic impedance of the transmission lines (TL1 to TL9) with impedance of the input termination resistor, including the input/output parasitic capacitance of the unit cell connected to the transmission lines, multiple reflection can be prevented, and thus stability of oscillation can be improved.

In the voltage-controlled oscillator 1 according to the present embodiment, the first unit cell 11, the second unit cell 12, and the compensation unit cell 13 have different transistor sizes (emitter lengths), but have the same circuit configuration. Here, different circuit configurations may be used for the first unit cell 11, the second unit cell 12, and the compensation unit cell 13.

### Modification Example 1

In the voltage-controlled oscillator according to a modification example 1 of the present embodiment, a size of the transistor used in the compensation unit cell 13 is larger than a size (emitter length) of the transistor used in the first unit cell 11 and the second unit cell 12. The other configuration is similar to the configuration of the voltage-controlled oscillator according to the first embodiment.

A gain of the compensation unit cell 13 is increased, and thus oscillation can be maintained by the compensation unit cell 13 even in a case where oscillation in the first unit cell 11 and the second unit cell 12 is stopped.

The voltage-controlled oscillator according to the present modification example can further stabilize oscillation.

Here, in a case where the size of the transistor used in the compensation unit cell 13 is increased, stability in oscillation continuation is improved. On the other hand, a center frequency of oscillation is lowered and a variable range of oscillation is narrowed.

Therefore, it is desirable that the size of the transistor used in the compensation unit cell 13 is twice the size (emitter length) of the transistor used in the first unit cell 11 and the second unit cell 12. For example, in a case where a bipolar transistor having an emitter length of 4 μm is used in each of the first unit cell 11 and the second unit cell 12, a bipolar transistor having an emitter length of 8 μm is used in the compensation unit cell 13.

In the voltage-controlled oscillator according to the present modification example, the compensation unit cell 13 including the bipolar transistor having an emitter length of 8 μm has a gain corresponding to two unit cells including the bipolar transistor having an emitter length of 4 μm.

In the configuration in the related art, oscillation is maintained with a gain obtained in a case where the first unit cell 11 or the second unit cell 12 including the bipolar transistor having an emitter length of 4 μm is turned on. On the other hand, in a case where the first unit cell 11 and the second unit cell 12 are turned off, oscillation is stopped.

On the other hand, in the voltage-controlled oscillator according to the present modification example, even in a case where the first unit cell 11 and the second unit cell 12 are turned off, a gain equivalent to the gain when the first unit cell 11 and the second unit cell 12 are turned on can be obtained only by the compensation unit cell 13 including the bipolar transistor having an emitter length of 8 μm. Therefore, oscillation can be maintained.

Thereby, in the voltage-controlled oscillator according to the modification example 1 of the present embodiment, it is possible to prevent oscillation from being stopped while maintaining a high center frequency and a wide variable range.

### Modification Example 2

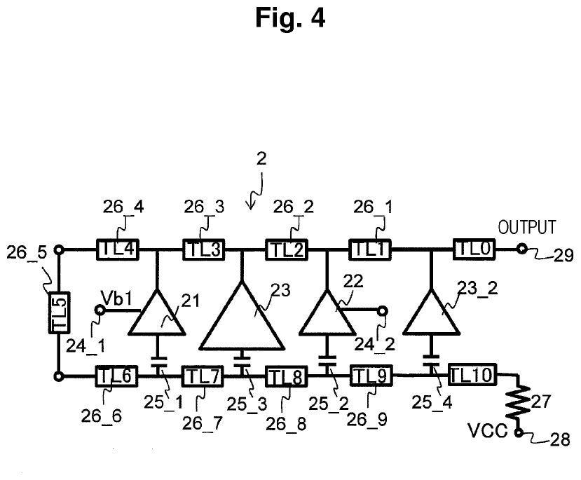

In a voltage-controlled oscillator 2 according to a modification example 2 of the present embodiment, as illustrated in FIG. 4, another second compensation unit cell 23_2 in a constant ON state is provided between the output terminal and the power supply voltage VCC terminal of the second unit cell 12 in the configuration according to the modification example 1.

According to the voltage-controlled oscillator 2 according to the present modification example, it is possible to increase the output power.

The second compensation unit cell 23_2 may have the same configuration as the first unit cell 21, the second unit cell 22, and the compensation unit cell 23.

### Modification Example 1

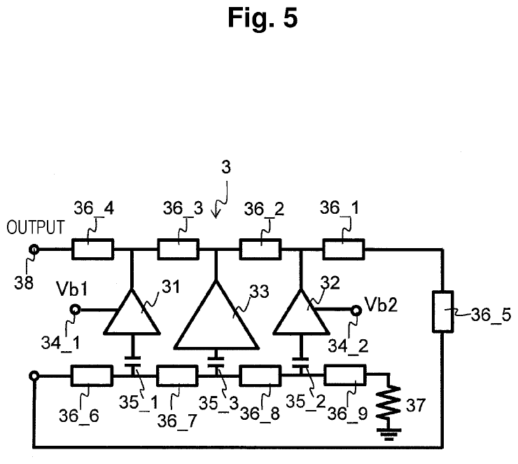

As illustrated in FIG. 5, a voltage-controlled oscillator according to a modification example 3 of the present embodiment is configured to operate in a forward gain mode. Thus, the variable range can be further extended.

In the forward gain mode in the voltage-controlled oscillator 3 according to the present modification example, an output of a distributed amplifier is connected to an input, and a termination resistor of the distributed amplifier serves as an output terminal of the distributed VCO.

### Second Embodiment

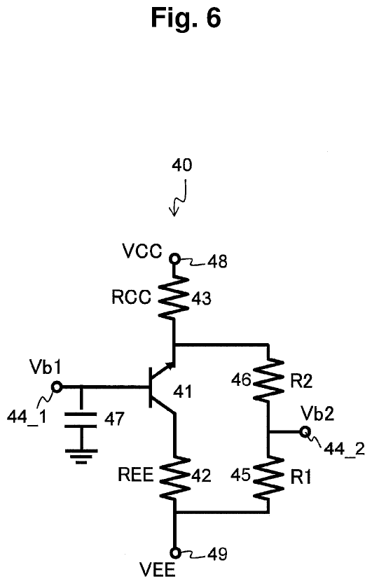

A voltage-controlled oscillator according to a second embodiment of the present invention will be described with reference to FIG. 6. A voltage-controlled oscillator 4 (similar to the voltage-controlled oscillator illustrated in FIG. 1A) according to the present embodiment has the same configuration as the configuration according to the first embodiment. In addition, a bias generation circuit 40 of the voltage-controlled oscillator generates a bias voltage Vb2 from a bias voltage Vb1.

As illustrated in FIG. 6, in the bias generation circuit 40 of the voltage-controlled oscillator according to the present embodiment, a resistor (REE) 42 and a resistor (RCC) 43 are respectively connected to an emitter and a collector of a transistor 41, and a capacitor 47 is connected to a base of the transistor 41 to which the bias voltage Vb1 in input. Two resistors 45 (R1) and 46 (R2) connected in series are connected in parallel to the transistor 41 and the resistor (REE) 42, and the bias voltage Vb2 is output from a connection point between the resistor 45 (R1) and the resistor 46 (R2).

The bias generation circuit 40 is connected to a Vb1 bias terminal 44_1 and a Vb2 bias terminal 44_2, and is included in the voltage-controlled oscillator.

The bias generation circuit 40 of the voltage-controlled oscillator automatically generates, from the voltage Vb1, the voltage Vb2 that symmetrically changes with the voltage Vb1. In a case where the voltage Vb1 is increased, a current flowing through the RCC increases, and the bias generation circuit 40 operates such that the voltage Vb2 symmetrically decreases.

Here, by changing a ratio between a resistance of the resistor (REE) 42 and a resistance of the resistor (RCC) 43, a slope of a change in the voltage Vb2 with respect to the voltage Vb1 can be changed.

In addition, by changing a ratio between a resistance of the resistor 45 (R1) and a resistance of the resistor 46 (R2), an offset can be given to the voltage Vb2.

According to the bias generation circuit of the voltage-controlled oscillator according to the present embodiment, it is possible to control the oscillation frequency of the distributed VCO only by the voltage Vb1.

Further, the voltage-controlled oscillator according to the present embodiment can be incorporated in a phase locked loop (PLL) using the voltage Vb1 as a control voltage.

The PLL includes the voltage-controlled oscillator according to the present embodiment, a phase comparator, a loop filter (or a low-pass filter), and an input reference signal source. The PLL operates with one control terminal, and thus the bias generation circuit according to the present embodiment can include one control terminal. Therefore, the voltage-controlled oscillator according to the present embodiment can be integrated into the PLL.

In the present embodiment, an example in which the configuration illustrated in FIG. 6 is used for the bias generation circuit 40 has been described. On the other hand, the present invention is not limited thereto, and the bias generation circuit may be a circuit that generates the voltage Vb2 which is symmetrical with respect to the voltage Vb1.

In the present embodiment, an example in which the bias generation circuit 40 is applied to the voltage-controlled oscillator according to the first embodiment has been described. On the other hand, the bias generation circuit may be applied to a voltage-controlled oscillator according to the modification example of the first embodiment.

In the embodiments of the present invention, in the configurations and the like of the voltage-controlled oscillator and the bias generation circuit, an example of a structure, a dimension, a material, and the like of each component has been described. On the other hand, the present invention is not limited thereto. Any structure, dimension, material, and the like that exhibit the functions and effects of the voltage-controlled oscillator and the bias generation circuit may be used.

### INDUSTRIAL APPLICABILITY

Embodiments of the present invention can be applied to devices and electronic circuits of devices that are used for optical communication, wireless communication, radar sensing, and the like.

### REFERENCE SIGNS LIST

1 Voltage-controlled oscillator
11, 12 Unit cell
13 Compensation unit cell
14_1, 14_2 Bias terminal
15_1 to 15_3 AC coupling capacitor
16_1 to 16_9 Transmission line (TL1 to TL9)
17 Input termination resistor
18 Power supply voltage terminal

1-8. (canceled)

9. A voltage-controlled oscillator comprising:
a first unit cell;
a second unit cell connected in parallel to the first unit cell via transmission lines;
a compensation unit cell connected in parallel with the first unit cell and the second unit cell between the first unit cell and the second unit cell; and
an input termination resistor connected to a power supply voltage terminal of each of the first unit cell, the second unit cell, and the compensation unit cell;
wherein the first unit cell and the second unit cell are configured to receive symmetrical voltages; and
wherein the compensation unit cell is configured to compensate for a gain by the first unit cell or the second unit cell.

10. The voltage-controlled oscillator according to claim 9, wherein a characteristic impedance of the transmission lines is matched with an input/output parasitic capacitance of each of the first unit cell, the second unit cell, and the compensation unit cell and an impedance of the input termination resistor.

11. The voltage-controlled oscillator according to claim 9, wherein each of the first unit cell, the second unit cell, and the compensation unit cell comprises:
a first transistor, wherein a base of the first transistor is connected to a bias terminal via a resistor; and
a second transistor connected in series to the first transistor.

12. The voltage-controlled oscillator according to claim 9, wherein a size of a transistor of the compensation unit cell is larger than a size of a transistor of the first unit cell.

13. The voltage-controlled oscillator according to claim 12, wherein the size of the transistor of the compensation unit cell is twice the size of the transistor of the first unit cell.

14. The voltage-controlled oscillator according to claim 9, further comprising a second compensation unit cell provided between an output terminal and the power supply voltage terminal of the second unit cell.

15. The voltage-controlled oscillator according to claim 9, wherein the voltage-controlled oscillator is configured to operate in a forward gain mode.

16. The voltage-controlled oscillator according to claim 9, further comprising a bias generation circuit configured to output a voltage that is input to the first unit cell and the second unit cell.

17. The voltage-controlled oscillator according to claim 16, wherein the bias generation circuit comprises:
a transistor,
an emitter resistor connected to an emitter of the transistor,
a collector resistor connected to a collector of the transistor;
a capacitor connected to a base of the transistor; and
two resistors connected in series and connected in parallel to the transistor and the emitter resistor.

18. A bias generation circuit comprising:
a transistor,
an emitter resistor connected to an emitter of the transistor,
a collector resistor connected to a collector of the transistor;
a capacitor connected to a base of the transistor; and
two resistors connected in series and connected in parallel to the transistor and the emitter resistor:
wherein the bias generation circuit is configured to output a voltage that is input to a first unit cell and a second unit cell of a voltage-controlled oscillator, the second unit cell being connected in parallel to the first unit cell via transmission lines, and the voltage-controlled oscillator further comprising:
a compensation unit cell connected in parallel with the first unit cell and the second unit cell between the first unit cell and the second unit cell; and
an input termination resistor connected to a power supply voltage terminal of each of the first unit cell, the second unit cell, and the compensation unit cell;
wherein the first unit cell and the second unit cell are configured to receive symmetrical voltages; and
wherein the compensation unit cell is configured to compensate for a gain by the first unit cell or the second unit cell.

19. A method of providing a voltage-controlled oscillator, the method comprising:
connecting a first unit cell and a second unit cell in parallel via transmission lines;
connecting a compensation unit cell in parallel with the first unit cell and the second unit cell between the first unit cell and the second unit cell; and
connecting an input termination resistor to a power supply voltage terminal of each of the first unit cell, the second unit cell, and the compensation unit cell;
wherein symmetrical voltages are to be supplied to the first unit cell and the second unit cell; and
wherein the compensation unit cell is to compensate for a gain by the first unit cell or the second unit cell.

20. The method according to claim 19, wherein a characteristic impedance of the transmission lines is matched with an input/output parasitic capacitance of each of the first unit cell, the second unit cell, and the compensation unit cell and an impedance of the input termination resistor.

21. The method according to claim 19, wherein each of the first unit cell, the second unit cell, and the compensation unit cell comprises:
a first transistor, wherein a base of the first transistor is connected to a bias terminal via a resistor; and
a second transistor connected in series to the first transistor.

22. The method according to claim 19, wherein a size of a transistor of the compensation unit cell is larger than a size of a transistor of the first unit cell.

23. The method according to claim 22, wherein the size of the transistor of the compensation unit cell is twice the size of the transistor of the first unit cell.

24. The method according to claim 19, further comprising providing a second compensation unit cell between an output terminal and the power supply voltage terminal of the second unit cell.

25. The method according to claim 19, wherein the voltage-controlled oscillator operates in a forward gain mode.

26. The method according to claim 19, further comprising providing a bias generation circuit that outputs a voltage that is input to the first unit cell and the second unit cell.

27. The method according to claim 26, wherein the bias generation circuit comprises:
a transistor,
an emitter resistor connected to an emitter of the transistor,
a collector resistor connected to a collector of the transistor;
a capacitor connected to a base of the transistor; and
two resistors connected in series and connected in parallel to the transistor and the emitter resistor.
